(19) United States
(12) Patent Application Publication
(10) Pub. No.: US 2025/0380448 A1
(43) Pub. Date: Dec. 11, 2025

(54) SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: HIROKI TSUMA, Nisshin-shi (JP); TOSHIKI MII, Nisshin-shi (JP); MASATO NOBORIO, Nisshin-shi (JP); JUN SAITO, Nisshin-shi (JP)

(21) Appl. No.: 19/204,725

(22) Filed: May 12, 2025

(30) Foreign Application Priority Data
Jun. 7, 2024 (JP) 2024-093247

(51) Int. Cl. H10D 30/66; H10D 62/10; H10D 62/832

(52) U.S. Cl. CPC H10D 30/665; H10D 30/668; H10D 62/106; H10D 62/115; H10D 62/124; H10D 62/8325

(57) ABSTRACT

The semiconductor device includes a semiconductor substrate partitioned into an active region, a peripheral high-breakdown-voltage region, and a boundary region disposed between the active region and the peripheral high-breakdown-voltage region. The semiconductor device further includes a main electrode, an insulating layer disposed in at least a portion of the boundary region and having an end portion facing the active region, a gate wiring disposed above the insulating layer, a gate electrode disposed in the active region, and a gate lead portion connecting the gate electrode and the gate wiring and extending above the end portion of the insulating layer. The boundary region includes a first semiconductor layer of a first conductivity type and a second semiconductor layer of a second conductivity type disposed above the first semiconductor layer. The second semiconductor layer has a contact portion in contact with the main electrode at a position outside the gate wiring.

### CROSS REFERENCE TO RELATED APPLICATION

The present application claims the benefit of priority from Japanese Patent Application No. 2024-093247 filed on Jun. 7, 2024. The entire disclosure of the above application is incorporated herein by reference.

### TECHNICAL FIELD

The present disclosure relates to a semiconductor device.

### BACKGROUND

Conventionally, there has been known a semiconductor device having a semiconductor substrate partitioned into an active region, a peripheral high-breakdown-voltage region, and a boundary region. The peripheral high-breakdown-voltage region is disposed to continuously surround the active region. The boundary region is disposed between the active region and the peripheral high-breakdown-voltage region and continuously surrounds the active region.

### SUMMARY

A semiconductor device of an example of the present disclosure includes a semiconductor substrate partitioned into an active region, a peripheral high-breakdown-voltage region, and a boundary region disposed between the active region and the peripheral high-breakdown-voltage region. The semiconductor device further includes a main electrode, an insulating layer disposed in at least a portion of the boundary region and having an end portion facing the active region, a gate wiring disposed above the insulating layer, a gate electrode disposed in the active region, and a gate lead portion connecting the gate electrode and the gate wiring and extending above the end portion of the insulating layer. The boundary region includes a first semiconductor layer of a first conductivity type and a second semiconductor layer of a second conductivity type disposed above the first semiconductor layer. The second semiconductor layer has a contact portion in contact with the main electrode at a position outside the gate wiring.

### BRIEF DESCRIPTION OF DRAWINGS

Objects, features and advantages of the present disclosure will become apparent from the following detailed description made with reference to the accompanying drawings. In the drawings:

FIG. 1 is a planar layout diagram of a semiconductor device according to a first embodiment, and is a diagram illustrating the positional relationship between an active region, a boundary region, and a peripheral high-breakdown-voltage region defined in a semiconductor substrate when the semiconductor substrate is viewed in plan;

FIG. 2 is a cross-sectional view of a portion of the semiconductor device according to the first embodiment, and is a diagram schematically illustrating a cross section including a trench gate taken along line II-II of FIG. 1;

FIG. 3 is a cross-sectional view of another portion of the semiconductor device according to the first embodiment, and is a diagram schematically illustrating a cross section without a trench gate taken along line III-III in FIG. 1;

FIG. 4 is a diagram illustrating a cross-sectional view of another portion of the semiconductor device according to the first embodiment, and is a diagram schematically illustrating a cross section taken along line IV-IV of FIG. 1;

FIG. 5 is an enlarged cross-sectional view of another portion of the semiconductor device according to the first embodiment, and is a diagram schematically illustrating a cross section in the vicinity of a tapered end portion of a field insulating layer;

FIG. 6 is a diagram illustrating paths of a displacement current in the cross section corresponding to FIG. 4;

FIG. 7 is a planar layout diagram of a semiconductor device according to a second embodiment, and is a diagram illustrating the positional relationship between an active region, a boundary region, and a peripheral high-breakdown-voltage region defined in a semiconductor substrate when the semiconductor substrate is viewed in plan; and

FIG. 8 is a cross-sectional view of a portion of the semiconductor device according to the second embodiment, and is a diagram schematically illustrating a cross section taken along line VIII-VIII of FIG. 7.

### DETAILED DESCRIPTION

Next, relevant technology is described to facilitate understanding of the following embodiments. A semiconductor device includes a semiconductor substrate partitioned into an active region, a peripheral high-breakdown-voltage region, and a boundary region. The peripheral high-breakdown-voltage region is disposed to continuously surround the active region. The boundary region is disposed between the active region and the peripheral high-breakdown-voltage region and continuously surrounds the active region. A gate electrode is disposed in the active region, and a current flowing through the active region is controlled according to a voltage applied to the gate electrode. The peripheral high-breakdown-voltage region has a peripheral high-breakdown-voltage structure such as a guard ring. An insulating layer is disposed above the semiconductor substrate located in the boundary region, and a gate wiring is disposed on the insulating layer. A gate lead portion is led out from the gate electrode disposed in the active region, and the gate lead portion extends above an end portion of the insulating layer and is connected to the gate wiring.

The boundary region of the semiconductor substrate includes an n-type semiconductor layer and a p-type semiconductor layer disposed above the n-type semiconductor layer. The n-type semiconductor layer is a semiconductor layer referred to as a drift layer or the like. The p-type semiconductor layer is a portion that extends in the boundary region from a semiconductor layer referred to as a p-type body layer or a p-type base layer, or the like, disposed in the active region toward the peripheral high-breakdown-voltage region.

When a sudden voltage change occurs in the voltage between main electrodes, a displacement current flows to charge and discharge a capacitance of a pn junction between the p-type semiconductor layer and the n-type semiconductor layer. For example, when a diode disposed in the semiconductor device is turned off, a sudden voltage change occurs in the voltage between the main electrodes, causing a displacement current to flow. The displacement current flows laterally through the p-type semiconductor layer toward the active region and enters the portion where the p-type semiconductor layer is in contact with the main electrode. At this time, the displacement current passes through the p-type semiconductor layer below the end portion of the insulating layer. A potential of the p-type semiconductor layer located below the end portion of the insulating layer rises based on a product of the displacement current and a resistance of the p-type semiconductor layer.

According to the study by the present inventors, it has become clear that when the displacement current flows, an electric field is concentrated at the end portion of the insulating layer.

A semiconductor device according to an aspect of the present disclosure includes a semiconductor substrate, a main electrode, an insulating layer, a gate wiring, a gate electrode, and a gate lead portion. The semiconductor substrate has a first main surface and a second main surface, and is partitioned into an active region, a peripheral high-breakdown-voltage region, and a boundary region. The peripheral high-breakdown-voltage region is disposed to continuously surround the active region. The boundary region is disposed between the active region and the peripheral high-breakdown-voltage region to continuously surround the active region. The main electrode is disposed above the first main surface of the semiconductor substrate. The insulating layer is disposed above the first main surface of the semiconductor substrate, is disposed in at least a portion of the boundary region, and has an end portion facing the active region. The gate wiring is disposed above the insulating layer and extends along the boundary region. The gate electrode is disposed in the active region of the semiconductor substrate. The gate lead portion connects the gate electrode and the gate wiring and extends above the end portion of the insulating layer. The boundary region of the semiconductor substrate includes a first semiconductor layer of a first conductivity type, and a second semiconductor layer of a second conductivity type disposed above the first semiconductor layer and disposed at a position where a surface of the second semiconductor layer forms the first main surface. The second semiconductor layer has a contact portion at a position outside the gate wiring, and the contact portion is in contact with the main electrode.

In the above-described semiconductor device, a part of a displacement current flowing through the second semiconductor layer branches off and flows into the contact portion disposed outside the gate wiring. Therefore, the displacement current flowing through the second semiconductor layer located below the end portion of the insulating layer is reduced, so that the potential rise in this portion is suppressed. As a result, the electric field concentration at the end portion of the insulating layer when a displacement current flows is alleviated.

### First Embodiment

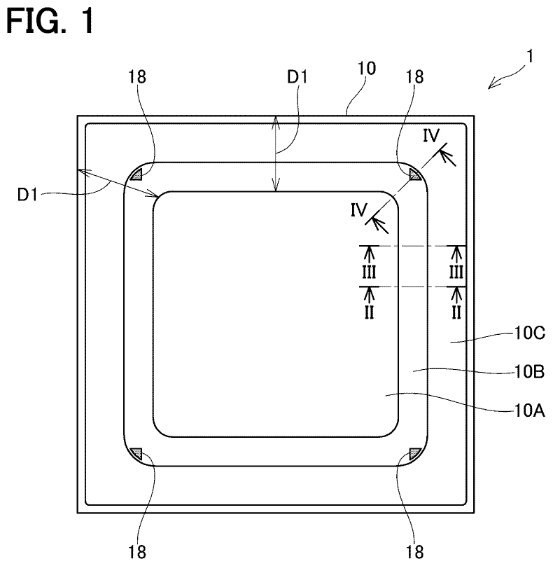

As shown in FIG. 1, a semiconductor device 1 of the first embodiment is configured using a semiconductor substrate 10. The material of the semiconductor substrate 10 is not particularly limited but may be silicon carbide (SiC), for example.

The semiconductor substrate 10 has the shape of rectangular flat plate. When viewed from a direction perpendicular to a main surface of the semiconductor substrate 10 (hereinafter referred to as “when viewed in plan”), the semiconductor substrate 10 is partitioned into an active region 10A, a boundary region 10B, and a peripheral high-breakdown-voltage region 10C. The active region 10A is a region disposed at the central side of the semiconductor substrate 10 and is a region where a switching structure for controlling current is formed. The switching structure includes a gate structure as described below and may be, but is not limited to, a metal oxide semiconductor field effect transistor (MOSFET) or a reverse conducting insulated gate bipolar transistor (IGBT). The boundary region 10B is a region disposed between the active region 10A and the peripheral high-breakdown-voltage region 10C to continuously surround the periphery of the active region 10A. The peripheral high-breakdown-voltage region 10C is a region disposed around the active region 10A and the boundary region 10B to continuously surround the active region 10A and the boundary region 10B. In the peripheral high-breakdown-voltage region 10C, a peripheral high-breakdown-voltage structure such as a guard ring is formed.

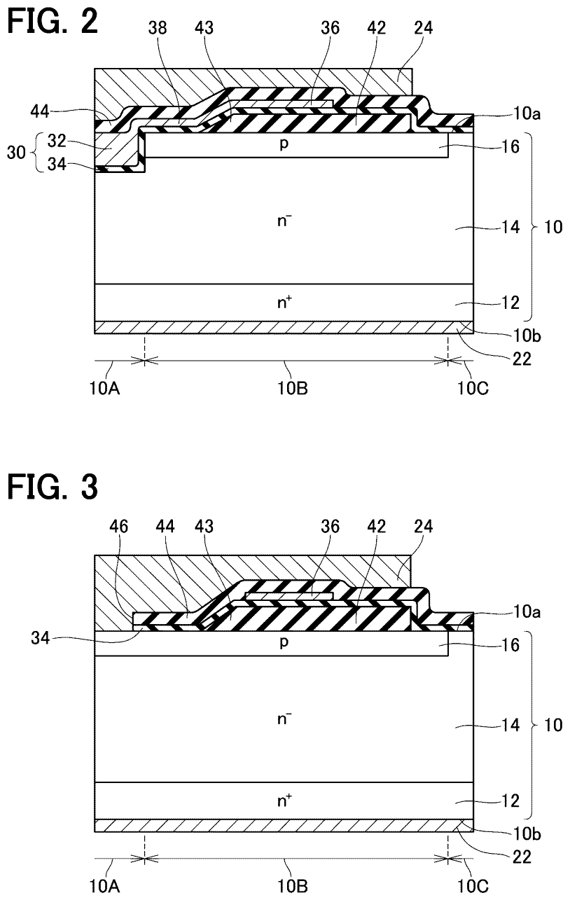

As shown in FIGS. 2 to 4, the semiconductor substrate 10 has a pair of main surfaces, that is, an upper surface 10a and a lower surface 10b. A drain electrode 22 is disposed on the lower surface 10b of the semiconductor substrate 10, and a source electrode 24 is disposed above the upper surface 10a of the semiconductor substrate 10. The semiconductor device 1 is a switching element that controls a current flowing between a pair of main electrodes, that is, the drain electrode 22 and the source electrode 24, and is a vertical switching element configured so that a current flows vertically through the semiconductor substrate 10. The semiconductor substrate 10 has a high-concentration n-type semiconductor layer 12, a low-concentration n-type semiconductor layer 14, and a p-type semiconductor layer 16.

The high-concentration n-type semiconductor layer 12 is a semiconductor layer containing a high-concentration of n-type impurities, and is also referred to as a drain layer. The high-concentration n-type semiconductor layer 12 is disposed continuously in the active region 10A, the boundary region 10B, and the peripheral high-breakdown-voltage region 10C, and is disposed at a position exposed at the lower surface 10b of the semiconductor substrate 10.

The low-concentration n-type semiconductor layer 14 is a semiconductor layer containing a lower concentration of n-type impurities than the high-concentration n-type semiconductor layer 12, and is also referred to as a drift layer. The low-concentration n-type semiconductor layer 14 is disposed continuously in the active region 10A, the boundary region 10B, and the peripheral high-breakdown-voltage region 10C. In the boundary region 10B, the low-concentration n-type semiconductor layer 14 is disposed between the high-concentration n-type semiconductor layer 12 and the p-type semiconductor layer 16. The low-concentration n-type semiconductor layer 14 is an example of a first semiconductor layer.

The p-type semiconductor layer 16 is a semiconductor layer containing p-type impurities, and is a portion that extends into the boundary region 10B from a p-type body layer or a p-type base layer formed in the active region 10A of the semiconductor substrate 10 toward the peripheral high-breakdown-voltage region 10C. In the boundary region 10B, the p-type semiconductor layer 16 is disposed above the low-concentration n-type semiconductor layer 14, and is disposed at a position where a surface of the p-type semiconductor layer 16 forms the upper surface 10a of the semiconductor substrate 10. The p-type semiconductor layer 16 is an example of a second semiconductor layer.

The semiconductor device 1 further includes a plurality of trench gates 30, a field insulating layer 42, and an interlayer insulating layer 44. The semiconductor device 1 may have a planar gate structure instead of the trench gates 30.

The trench gates 30 are disposed in the active region 10A and extend in one direction within the active region 10A from one end to the other end of the active region 10A when the semiconductor substrate 10 is viewed in plan. The trench gates 30 are disposed in the active region 10A and are arranged in a stripe pattern when the semiconductor substrate 10 is viewed in plan. The arrangement of the trench gates 30 is not limited to the stripe pattern and may have other layouts. In the present embodiment, an area where the trench gates 30 are disposed is the active region 10A, an area where the p-type semiconductor layer 16 is disposed, that is, an area from the ends of the trench gates 30 to an outer boundary of the p-type semiconductor layer 16 is the boundary region 10B, and an area outside the p-type semiconductor layer 16 is the peripheral high-breakdown-voltage region 10C.

Each of the trench gates 30 includes a gate electrode 32 and a gate insulating layer 34. The gate electrode 32 is insulated from the semiconductor substrate 10 by the gate insulating layer 34 and is insulated from the source electrode 24 by the interlayer insulating layer 44. The gate insulating layer 34 extends beyond the field insulating layer 42 to the upper surface 10a of the semiconductor substrate 10 located in the peripheral high-breakdown-voltage region 10C.

The field insulating layer 42 is disposed on at least a part of an area of the upper surface 10a of the semiconductor substrate 10 located in the boundary region 10B. The field insulating layer 42 has a tapered end portion 43 that has a tapered shape. The tapered end portion 43 is an end of the field insulating layer 42 that is closer to the active region 10A and is a portion that is thinner than the maximum layer thickness of the field insulating layer 42. In this example, the thickness of the tapered end portion 43 gradually decreases toward the active region 10A, and an upper surface of the tapered end portion 43 is inclined toward the active region 10A. Alternatively, the tapered end portion 43 may be configured such that the thickness of the field insulating layer 42 decreases in a step-like manner.

Above the field insulating layer 42, a gate wiring 36 is disposed. The gate wiring 36 extends from a gate pad (not shown) disposed on the semiconductor substrate 10 and extends above the field insulating layer 42 along the boundary region 10B. The gate wiring 36 may be disposed around the periphery of the active region 10A along the boundary region 10B, or may be disposed in a portion of the periphery of the active region 10A along the boundary region 10B.

As shown in FIG. 2, a gate lead portion 38 is led out from an end portion of the gate electrode 32. The gate lead portion 38 extends above the tapered end portion 43 of the field insulating layer 42 and connects the gate electrode 32 and the gate wiring 36. In other words, the gate lead portion 38 is a wiring portion between the gate electrode 32 and the gate wiring 36. As shown in FIG. 5, if a layer thickness of the gate lead portion 38 is Tg and a width of the tapered end portion 43 of the field insulating layer 42, that is, a width of the tapered end portion 43 in a cross section perpendicular to the direction in which a tip of the field insulating layer 42 extends when the semiconductor substrate 10 is viewed in plane, is L, then the relationship Tg<L holds. When such a relationship is established, it is possible to prevent the gate lead portion 38 from being disconnected at the portion where the gate lead portion extends above the field insulating layer 42.

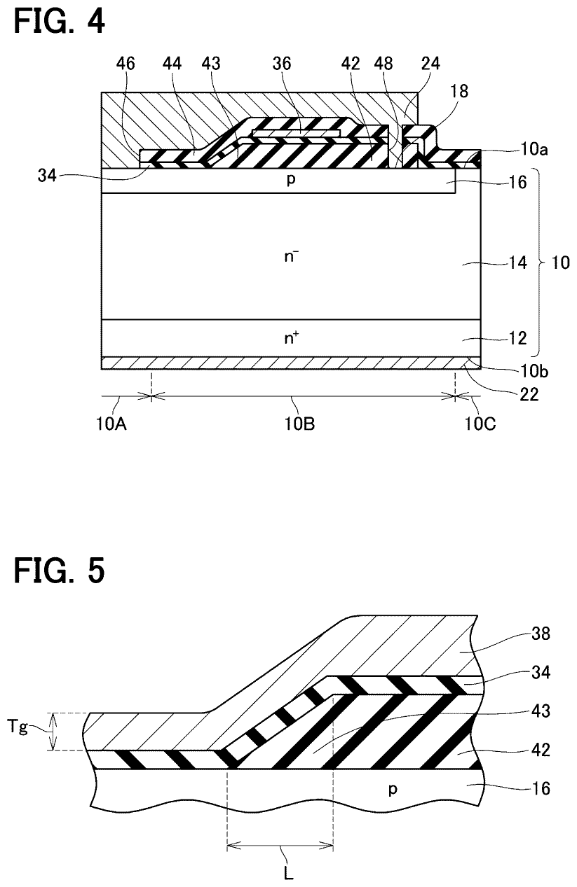

As shown in FIG. 2, the interlayer insulating layer 44 covers the gate electrode 32, the gate wiring 36, and the gate lead portion 38, and insulates them from the source electrode 24. As shown in FIG. 3 and FIG. 4, the interlayer insulating layer 44 has an opening 46 to expose the upper surface 10a of the semiconductor substrate 10 located in the active region 10A. The source electrode 24 is in contact with the upper surface 10a of the semiconductor substrate 10 through the opening 46 in the interlayer insulating layer 44. The source electrode 24 extends above the interlayer insulating layer 44 in the boundary region 10B from the active region 10A toward the peripheral high-breakdown-voltage region 10C.

As shown in FIG. 4, the interlayer insulating layer 44 further has through holes 48 that penetrate the gate insulating layer 34 and the field insulating layer 42. The through holes 48 are formed in the boundary region 10B and outside the gate wiring 36, that is, at positions closer to the peripheral high-breakdown-voltage region 10C than the gate wiring 36, and expose the p-type semiconductor layer 16. The portions of the p-type semiconductor layer 16 exposed in the through holes 48 are referred to as contact portions 18. The through holes 48 are filled with the source electrode 24, and the source electrode 24 is in contact with the contact portions 18 of the p-type semiconductor layer 16. The through holes 48 may be formed outside the field insulating layer 42 to penetrate the interlayer insulating layer 44 and the gate insulating layer 34.

In FIG. 1, formation areas of the contact portions 18 of the p-type semiconductor layer 16 are indicated by hatching. The contact portions 18 are disposed only at corner portions of the boundary region 10B. The corner portions of the boundary region 10B are defined by at least one of the following. If a distance from an edge of the semiconductor substrate 10 (that is, a chip edge) to the active region 10A is D1, portions of the boundary region 10B located in areas where the distance D1 is not the smallest may be defined as the corner portions. As described above, the boundary region 10B is the area where the p-type semiconductor layer 16 is disposed. The p-type semiconductor layer 16 disposed around the active region 10A, which has an approximately rectangular shape, has curved portions at its outer boundary when the semiconductor substrate 10 is viewed in plan. Portions of the boundary region 10B located inside the curved portions of the outer boundary of the p-type semiconductor layer 16 may be defined as corner portions.

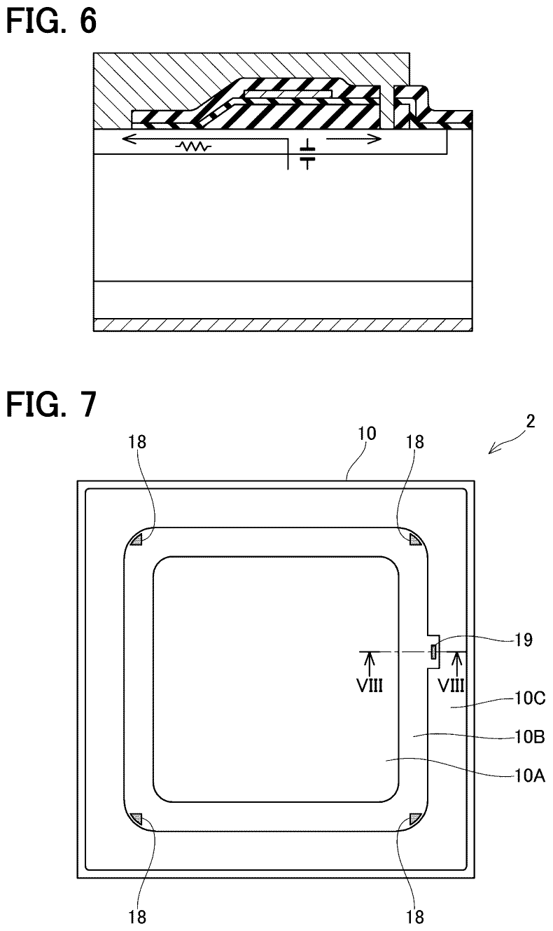

Next, the features of the semiconductor device 1 will be described with reference to FIG. 6. FIG. 6 corresponds to FIG. 4, and reference numerals are omitted for the purpose of clarity of the drawing. When a sudden voltage change occurs in the voltage between the drain electrode 22 and the source electrode 24, a displacement current flows to charge and discharge a capacitance of a pn junction between the p-type semiconductor layer 16 and the low-concentration n-type semiconductor layer 14. For example, when a diode disposed in the semiconductor device 1 is turned off, a sudden voltage change occurs in the voltage between the drain electrode 22 and the source electrode 24, causing a displacement current to flow.

Here, a comparative example in which the p-type semiconductor layer 16 does not have the contact portions 18 will be considered. The displacement current flows laterally through the p-type semiconductor layer 16 toward the active region 10A and flows into a portion of the p-type semiconductor layer 16 in the active region 10A where the p-type semiconductor layer 16 is in contact with the source electrode 24. At this time, the displacement current passes through the p-type semiconductor layer 16 located below the tapered end portion 43 of the field insulating layer 42. A potential of the p-type semiconductor layer 16 located below the tapered end portion 43 of the field insulating layer 42 rises based on a product of the displacement current and a resistance of the p-type semiconductor layer 16. In the semiconductor device in which the end portion of the field insulating layer 42 is formed to be tapered, an electric field is likely to concentrate at the tapered end portion 43 of the field insulating layer 42 when the displacement current flows. Such electric field concentration is prominent when the end portion of the field insulating layer 42 is tapered, but an electric field concentration can also occur when the end portion of the field insulating layer 42 is not tapered.

On the other hand, in the semiconductor device 1 of the present embodiment, a part of the displacement current flowing through the p-type semiconductor layer 16 branches off and flows into the contact portions 18 disposed outside the gate wiring 36. Therefore, the displacement current flowing through the p-type semiconductor layer 16 located below the tapered end portion 43 of the field insulating layer 42 is reduced, so that the potential rise in this portion is suppressed. As a result, the electric field concentration at the tapered end portion 43 of the field insulating layer 42 when a displacement current flows is alleviated. Therefore, the semiconductor device 1 can have a high resistance to the sudden voltage change in the voltage between the drain electrode 22 and the source electrode 24.

As described above, the contact portions 18 of the p-type semiconductor layer 16 are disposed at the corner portions of the boundary region 10B. The corner portions of the boundary region 10B are locations where the displacement current flowing toward the active region 10A concentrates and the current density becomes high, and are locations where electric field concentration at the tapered end portion 43 of the field insulating layer 42 is likely to become a problem. In the semiconductor device 1, by forming the contact portions 18 of the p-type semiconductor layer 16 at the corner portions of the boundary region 10B, such electric field concentration can be effectively alleviated. The contact portions 18 of the p-type semiconductor layer 16 are disposed only at the corner portions of the boundary region 10B, and are not disposed in linear portions of the boundary region 10B. Therefore, it is not necessary to widen the width of the boundary region 10B just to form the contact portions 18, so that an increase in the area of the semiconductor device 1 can be suppressed.

Furthermore, when the semiconductor substrate 10 of the semiconductor device 1 is made of silicon carbide (SiC), the resistance of the p-type semiconductor layer 16 is high, and the potential of the p-type semiconductor layer 16 is likely to increase. For this reason, the technique of forming the contact portions 18 in the p-type semiconductor layer 16 is particularly useful when the material of the semiconductor substrate 10 is silicon carbide (SIC).

### Second Embodiment

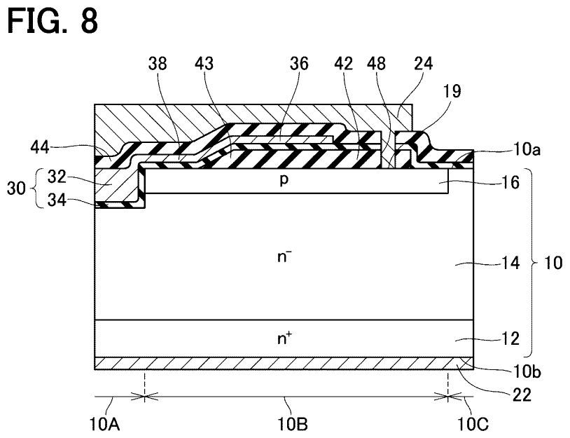

FIG. 7 and FIG. 8 illustrate a semiconductor device 2 according to a second embodiment. The same components as those of the semiconductor device 1 of the first embodiment are denoted by the same reference numerals, and the description thereof will be omitted.

As shown in FIG. 7, in the semiconductor device 2, when the semiconductor substrate 10 is viewed in plan, a part of the straight line portion in the boundary region 10B is expanded outward to have a larger width. That is, in the semiconductor device 2, when the semiconductor substrate 10 is viewed in plan, the outer boundary of a part of the straight portion of the p-type semiconductor layer 16 is expanded outward to increase the width of that part. In the semiconductor device 2, a contact portion 19 is also formed in the wide portion of the p-type semiconductor layer 16.

For various reasons, it may be desirable to form some portions of the p-type semiconductor layer 16 wider than other portions. In this case, the current density of the displacement current increases in the wide portion of the p-type semiconductor layer 16, so that when the displacement current flows, the electric field is likely to concentrate at the tapered end portion 43 of the field insulating layer 42 in the wide portion of the p-type semiconductor layer 16. In the semiconductor device 2, by forming the contact portion 19 also in the wide portion of the p-type semiconductor layer 16, such electric field concentration can be effectively alleviated.

What is claimed is:

1. A semiconductor device comprising:
a semiconductor substrate having a first main surface and a second main surface, and partitioned into an active region, a peripheral high-breakdown-voltage region, and a boundary region, the peripheral high-breakdown-voltage region disposed to continuously surround the active region, the boundary region disposed between the active region and the peripheral high-breakdown-voltage region to continuously surround the active region;
a main electrode disposed above the first main surface of the semiconductor substrate;
an insulating layer disposed above the first main surface of the semiconductor substrate, disposed in at least a portion of the boundary region, and having an end portion facing the active region;
a gate wiring disposed above the insulating layer and extending along the boundary region;
a gate electrode disposed in the active region of the semiconductor substrate; and
a gate lead portion connecting the gate electrode and the gate wiring and extending above the end portion of the insulating layer, wherein
the boundary region of the semiconductor substrate includes:
a first semiconductor layer of a first conductivity type; and
a second semiconductor layer of a second conductivity type disposed above the first semiconductor layer and disposed at a position where a surface of the second semiconductor layer forms the first main surface, and
the second semiconductor layer has a contact portion at a position outside the gate wiring, and the contact portion is in contact with the main electrode.

2. The semiconductor device according to claim 1, wherein
the contact portion is disposed only at a corner portion of the boundary region when the semiconductor substrate is viewed in plan.

3. The semiconductor device according to claim 1, wherein
the end portion of the insulating layer has a tapered end portion that is tapered toward the active region.

4. The semiconductor device according to claim 3, wherein
a width of the tapered end portion of the insulating layer is greater than a thickness of the gate lead portion.

5. The semiconductor device according to claim 1, wherein
the semiconductor substrate is made of silicon carbide.
